(19) United States
(12) Patent Application Publication
(10) Pub. No.: US 2018/0188651 A1
(43) Pub. Date: Jul. 5, 2018

(54) PHOTOSENSITIVE COMPOSITION

(71) Applicant: TAIFLEX Scientific Co., Ltd., KAOHSIUNG (TW)

(72) Inventors: Shih-Chang Lin, KAOHSIUNG (TW); Yi-Ming Chen, KAOHSIUNG (TW); Chiu-Feng Chen, KAOHSIUNG (TW); Chun-Yi Kuo, KAOHSIUNG (TW)

(73) Assignee: TAIFLEX Scientific Co., Ltd., KAOHSIUNG (TW)

(21) Appl. No.: 15/450,036

(22) Filed: Mar. 6, 2017

(30) Foreign Application Priority Data
Jan. 3, 2017 (TW) 106100085

(51) Int. Cl. G03F 7/038; C08G 73/10

(52) U.S. Cl. CPC G03F 7/0387; C08G 73/1082

(57) ABSTRACT

A photosensitive composition is provided. The photosensitive composition includes a composition for forming polyimide, a photoinitiator, a photo cross-linking agent, and a thermal cross-linking agent. The composition for forming polyimide includes a diamine monomer component, an anhydride monomer component, and a polyimide modifier. The diamine monomer component includes a long-chain aliphatic diamine monomer, a carboxylic acid-containing diamine monomer, and a triazole compound. The anhydride monomer component includes a dianhydride monomer and a monoanhydride monomer. The polyimide modifier has a double bond and an epoxy group.

### CROSS-REFERENCE TO RELATED APPLICATION

This application claims the priority benefit of Taiwan application serial no. 106100085, filed on Jan. 3, 2017. The entirety of the above-mentioned patent application is hereby incorporated by reference herein and made a part of this specification.

### BACKGROUND OF THE INVENTION

### Field of the Invention

The invention relates to a composition, and more particularly, to a photosensitive composition.

### Description of Related Art

A film formed by a photosensitive solder resist composition in which epoxy resin is used as the main agent for a regular flexible circuit board is not suitable for a flexible circuit board of a high-density circuit due to drawbacks such as insufficient solder resistance, mechanical strength, and flame retardance. Therefore, current techniques attempt to replace the epoxy resin with photosensitive polyimide. However, in the forming process of a film by a photosensitive solder resist composition in which photosensitive polyimide is used as the main agent in current techniques, the developing solution used contains an organic solvent and the aging temperature is higher than 200° C., such that an aging process needs to be performed in a nitrogen oven. As a result, the process needs of a flexible circuit board of a high-density circuit still cannot be met.

### SUMMARY OF THE INVENTION

The invention provides a photosensitive composition that can be developed using an alkaline aqueous solution and aged at low temperature.

A photosensitive composition of the invention includes a composition for forming polyimide, a photoinitiator, a photo cross-linking agent, and a thermal cross-linking agent. The composition for forming polyimide includes a diamine monomer component, an anhydride monomer component, and a polyimide modifier. The diamine monomer component includes a long-chain aliphatic diamine monomer, a carboxylic acid-containing diamine monomer, and a triazole compound. The anhydride monomer component includes a dianhydride monomer and a monoanhydride monomer. The polyimide modifier has a double bond and an epoxy group.

In an embodiment of the invention, the long-chain aliphatic diamine monomer has a C₆ to C₄₀ main chain.

In an embodiment of the invention, the carboxylic acid-containing diamine monomer includes methylene bis(anthranilic acid) or 3,5-diaminobenzoic acid.

In an embodiment of the invention, the triazole compound includes 3,5-diamino-1,2,4-triazole or benzotriazole.

In an embodiment of the invention, the dianhydride monomer includes bis-(3-phthalyl anhydride)ether, 3,3′,4,4′-benzophenonetetracarboxylic dianhydride, 3,3′,4,4′-biphenyltetracarboxylic dianhydride, bicyclo[2.2.2]oct-7-ene-2,3,5,6-tetracarboxylic dianhydride, or 4,4′-(hexafluoro-isopropylidene)diphthalic anhydride.

In an embodiment of the invention, the monoanhydride monomer includes trimellitic anhydride or phthalic anhydride.

In an embodiment of the invention, based on the total number of moles of the diamine monomer component, the content of the long-chain aliphatic diamine monomer is 15 mol % to 30 mol %, the content of the carboxylic acid-containing diamine monomer is 65 mol % to 75 mol %, and the content of the triazole compound is 3 mol % to 12 mol %.

In an embodiment of the invention, based on the total number of moles of the anhydride monomer component, the content of the dianhydride monomer is 80 mol % to 95 mol % and the content of the monoanhydride monomer is 5 mol % to 20 mol %.

In an embodiment of the invention, the mole ratio of the diamine monomer component and the anhydride monomer component is 1:1.

In an embodiment of the invention, the polyimide modifier includes glycidyl methacrylate or allyl glycidyl ether.

In an embodiment of the invention, based on the number of moles of the carboxylic acid-containing diamine monomer, the amount of the polyimide modifier is 0.2 mol % to 0.4 mol %.

In an embodiment of the invention, the photoinitiator includes phenyl bis(2,4,6-trimethylphenyl methyl)phosphine oxide or 2-benzyl-2-(dimethylamino)-1-[4-(4-morpholinyl)phenyl]-1-butanone.

In an embodiment of the invention, the photo cross-linking agent includes a trimethylolpropane trimethacrylate monomer, pentaerythritol triacrylate, 1,6-hexanediol diacrylate, dipentaerythritol hexaacrylate, or tri(propylene glycol)diacrylate.

In an embodiment of the invention, the thermal cross-linking agent includes 1,3-phenylenebisoxazoline or an epoxy resin.

In an embodiment of the invention, based on the total weight of the photosensitive composition, the content of the polyimide formed by the composition for forming polyimide is 65 wt % to 85 wt %, the content of the photoinitiator is 0.5 wt % to 5 wt %, the content of the photo cross-linking agent is 4 wt % to 10 wt %, and the content of the thermal cross-linking agent is 10 wt % to 20 wt %.

In an embodiment of the invention, the photosensitive composition further includes an adhesion promoter, wherein based on the total weight of the photosensitive composition, the content of the adhesion promoter is 0.1 wt % to 1.3 wt %.

In an embodiment of the invention, the adhesion promoter includes N-(triethoxysilylpropyl)urea, 1H-1,2,4-triazole-3-thiol, or 2-amino-5-mercapto-1,3,4-thiadiazole.

Based on the above, the photosensitive composition of the invention includes the composition for forming polyimide, the photoinitiator, the photo cross-linking agent, and the thermal cross-linking agent, wherein the composition for forming polyimide includes the diamine monomer component, the anhydride monomer component, and the polyimide modifier, the diamine monomer component includes the long-chain aliphatic diamine monomer, the carboxylic acid-containing diamine monomer, and the triazole compound, the anhydride monomer component includes the dianhydride monomer and the monoanhydride monomer, and the polyimide modifier has a double bond and an epoxy group. As a result, the photosensitive composition of the invention can be applied in exposure and developing processes, and can be developed using an alkaline aqueous solution and aged at a low temperature of less than 200° C. without the use of a nitrogen oven in the manufacturing process. Moreover, the product obtained by exposure and developing processes can have good acid and alkali resistance, solder resistance, solvent resistance, and thermal stability, and can have good adhesion with copper foil.

In order to make the aforementioned features and advantages of the invention more comprehensible, embodiments are described in detail below.

### DESCRIPTION OF THE EMBODIMENTS

In the present specification, a range represented by “a numerical value to another numerical value” is a schematic representation for avoiding listing all of the numerical values in the range in the specification. Therefore, the recitation of a specific numerical range covers any numerical value in the numerical range and a smaller numerical range defined by any numerical value in the numerical range, as is the case with the any numerical value and the smaller numerical range stated explicitly in the specification.

To prepare a photosensitive polyimide composition that can be developed using an alkaline aqueous solution and aged at low temperature, the invention provides a photosensitive composition that can achieve the above advantages. In the following, embodiments are provided as examples of actual implementation of the invention.

An embodiment of the invention provides a photosensitive composition, including a composition for forming polyimide, a photoinitiator, a photo cross-linking agent, and a thermal cross-linking agent. In the present embodiment, the viscosity of the photosensitive composition is between 2000 cps and 4000 cps. Hereinafter, the various components above are described in detail.

The composition for forming polyimide includes a diamine monomer component, an anhydride monomer component, and a polyimide modifier. In the present embodiment, the diamine monomer component includes a long-chain aliphatic diamine monomer, a carboxylic acid-containing diamine monomer, and a triazole compound. In other words, in the present embodiment, the diamine monomer component includes three types of diamine monomers. Moreover, in the present embodiment, based on the total number of moles of the diamine monomer component, the content of the long-chain aliphatic diamine monomer is 15 mol % to 30 mol %, preferably 20 mol % to 25 mol %, the content of the carboxylic acid-containing diamine monomer is 65 mol % to 75 mol %, preferably 68 mol % to 72 mol %, and the content of the triazole compound is 3 mol % to 12 mol %, preferably 5 mol % to 10 mol %. When the content of the long-chain aliphatic diamine monomer is less than 15 mol %, the resulting polyimide has the issue of poor film-forming properties; when the content of the long-chain aliphatic diamine monomer is higher than 30 mol %, the issue of poor development readily occurs in a subsequent developing process; when the content of the carboxylic acid-containing diamine monomer is less than 65 mol %, the issue of poor development readily occurs in a subsequent developing process; when the content of the carboxylic acid-containing diamine monomer is higher than 75 mol %, the resulting polyimide has the issue of poor film-forming properties; when the content of the triazole compound is less than 3 mol %, the issue of poor adhesion occurs when the polyimide after molding is to be combined with other elements (such as copper foil); and when the content of the triazole compound is higher than 12 mol %, the resulting polyimide has the issue of poor film-forming properties.

The long-chain aliphatic diamine monomer has a C₆ to C₄₀ main chain. When the carbon number of the main chain is less than 6, the molecular weight of the resulting polyimide is too small, such that the issue of poor film-forming properties occurs; and when the carbon number of the main chain is higher than 40, the molecular weight of the resulting polyimide is too large, such that the issue of poor development readily occurs. Moreover, in an embodiment, the long-chain aliphatic diamine monomer has a C₃₆ to C₄₀ main chain. Specifically, examples of the long-chain aliphatic diamine monomer include (but are not limited to): hexamethylenediamine, octanediamine, nonanediamine, decanediamine, 1,16-hexadecanediamine, or 1,18-octadecanediamine. Moreover, the long-chain aliphatic diamine monomer can also adopt a commercial product such as Priamine™ 1074-Dimer diamine or Priamine™ 1075 (made by Croda Japan) or Versamine 551 (made by BASF).

Examples of the carboxylic acid-containing diamine monomer include (but are not limited to): methylene bis(anthranilic acid) (MBAA) or 3,5-diaminobenzoic acid (DABZ).

Examples of the triazole compound include (but are not limited to): 3,5-diamino-1,2,4-triazole (DTA) or benzotriazole.

Moreover, in the present embodiment, the anhydride monomer component includes a dianhydride monomer and a monoanhydride monomer. In other words, in the present embodiment, the anhydride monomer component includes two types of anhydride monomers. Moreover, in the present embodiment, based on the total number of moles of the anhydride monomer component, the content of the dianhydride monomer is 80 mol % to 95 mol %, preferably 85 mol % to 90 mol %, and the content of the monoanhydride monomer is 5 mol % to 20 mol %, preferably 10 mol % to 15 mol %. When the content of the dianhydride monomer is less than 80 mol %, the anhydride monomer component is not readily dissolved in the solution; when the content of the dianhydride monomer is higher than 95 mol %, the resulting polyimide has the issue of poor heat resistance; when the content of the monoanhydride monomer is less than 5 mol %, the issue of poor development readily occurs in a subsequent developing process; and when the content of the monoanhydride monomer is higher than 20 mol %, the resulting polyimide has the issue of poor film-forming properties.

Examples of the dianhydride monomer include (but are not limited to): bis-(3-phthalyl anhydride)ether (ODPA), 3,3′,4,4′-benzophenonetetracarboxylic dianhydride (BTDA), 3,3′,4,4′-biphenyltetracarboxylic dianhydride (BPDA), bicyclo[2.2.2]oct-7-ene-2,3,5,6-tetracarboxylic dianhydride (BTA), or 4,4′-(hexafluoro-isopropylidene)diphthalic anhydride (6FDA).

Examples of the monoanhydride monomer include (but are not limited to): trimellitic anhydride, 1,2,4-benzenetricarbovylic anhydride (TMA), or phthalic anhydride.

It should be mentioned that, in the present embodiment, the diamine monomer component and the anhydride monomer component are reacted to form soluble polyimide. In an embodiment, the preparation method of the soluble polyimide includes, for instance, reacting the diamine monomer component and the anhydride monomer component in an imidization reaction in a solvent to form a solution containing soluble polyimide, wherein the mole ratio of the diamine monomer component and the anhydride monomer component is 1:1. The imidization reaction can be performed using any method known to those having ordinary skill in the art, such as thermal cyclization or chemical cyclization. Moreover, in the present step, the solvent includes, for instance, N-methyl-2-pyrrolidone (NMP), N,N-dimethylacetamide (DMAc), dimethylformamide (DMF), dimethyl sulfoxide (DMSO), 1,4-butyrolactone, or a combination thereof. Moreover, since the mole ratio of the diamine monomer component and the anhydride monomer component is 1:1, the composition for forming polyimide can form polyimide having the desired properties.

Moreover, since the diamine monomer component includes the carboxylic acid-containing diamine monomer, the side chain of the resulting polyimide has a carboxylic acid group.

The polyimide modifier has a double bond and an epoxy group. Specifically, in the present embodiment, the double bond and the epoxy group are respectively located at the two ends of the main carbon chain of the polyimide modifier. Specifically, examples of the polyimide modifier include (but are not limited to): glycidyl methacrylate or allyl glycidyl ether.

It should be mentioned that, in the present embodiment, the target of modification of the polyimide modifier is the soluble polyimide formed by the reaction of the diamine monomer component and the anhydride monomer component. As described above, the side chain of polyimide has a carboxylic acid group, and therefore the polyimide modifier can be grafted on polyimide via the reaction of the epoxy group and the carboxylic acid group to form modified soluble polyimide. More specifically, since the polyimide modifier has a double bond and an epoxy group, the side chain of the modified soluble polyimide has a carboxylic acid group and a double bond, and therefore the modified soluble polyimide is suitable for exposure and alkali developing processes. In other words, the composition for forming polyimide can produce photosensitive polyimide, that is, the modified soluble polyimide can be used as the photosensitive polyimide. Moreover, in the present embodiment, based on the number of moles of the carboxylic acid-containing diamine monomer, the amount of the polyimide modifier is 0.2 mol % to 0.4 mol %, preferably 0.25 mol % to 0.35 mol %. When the amount of the polyimide modifier is less than 0.2 mol % or higher than 0.4 mol %, the polyimide formed by the composition for forming polyimide does not have good developing effect.

From another perspective, in the present embodiment, the photosensitive composition includes photosensitive polyimide prepared by the composition for forming polyimide. In an embodiment, the preparation method of the photosensitive polyimide includes, for instance: adding the polyimide modifier in a solution containing soluble polyimide formed by the diamine monomer component and the anhydride monomer component to perform a grafting reaction to form a solution containing photosensitive polyimide. In an embodiment, in the above steps, the reaction temperature is, for instance, between 90° C. and 110° C.; and the reaction time is, for instance, between 3 hours and 5 hours, but the invention is not limited thereto.

In an embodiment, the photosensitive composition includes the photoinitiator, and therefore the photoinitiator can trigger a free-radical polymerization reaction during an exposure process. Specifically, examples of the photoinitiator include (but are not limited to): phenyl bis(2,4,6-trimethylphenyl methyl)phosphine oxide or 2-benzyl-2-(dimethylamino)-1-[4-(4-morpholinyl)phenyl]-1-butanone.

In an embodiment, Since the photosensitive composition includes the photo cross-linking agent, the photo cross-linking agent can be cross-linked with the photosensitive polyimide during the exposure process, so as to increase the degree of cross-linking of the photosensitive polyimide and increase the developing effect. Specifically, examples of the photo cross-linking agent include (but are not limited to): a trimethylolpropane trimethacrylate monomer, pentaerythritol triacrylate, 1,6-hexanediol diacrylate, polydipentaerythritol hexaacrylate, or tri(propylene glycol)diacrylate.

In an embodiment, Since the photosensitive composition includes the thermal cross-linking agent, the thermal cross-linking agent can be cross-linked with the photosensitive polyimide during the heating process, so as to increase the degree of cross-linking of the photosensitive polyimide. Specifically, examples of the thermal cross-linking agent include (but are not limited to): 1,3-phenylenebisoxazoline or an epoxy resin.

Moreover, in the present embodiment, based on the total weight of the photosensitive composition, the content of the photosensitive polyimide is 65 wt % to 85 wt %, preferably 70 wt % to 80 wt %, the content of the photoinitiator is 0.5 wt % to 5 wt %, preferably 2 wt % to 4 wt %, the content of the photo cross-linking agent is 4 wt % to 10 wt %, preferably 5 wt % to 8 wt %, and the content of the thermal cross-linking agent is 10 wt % to 20 wt %, preferably 12 wt % to 18 wt %. When the content of the photosensitive polyimide is less than 65 wt % or the content of the photosensitive polyimide is higher than 85 wt %, the product obtained from a subsequent process of the photosensitive composition has the issue of poor heat resistance; when the content of the photoinitiator is less than 0.5 wt % or the content of the photoinitiator is higher than 5 wt %, the photosensitive composition has the issue of poor photosensitive effect; when the content of the photo cross-linking agent is less than 4 wt %, the photosensitive composition readily has the issue of poor development; when the content of the photo cross-linking agent is higher than 10 wt %, the product obtained by a subsequent process of the photosensitive composition has the issue of poor flexibility; when the content of the thermal cross-linking agent is less than 10 wt %, the product obtained by a subsequent process of the photosensitive composition has the issue of poor film-forming properties; and when the content of the thermal cross-linking agent is higher than 20 wt %, the product obtained by a subsequent process of the photosensitive composition has the issue of poor flexibility.

It should be mentioned that, as described above, in the present embodiment, since the photosensitive composition includes polyimide formed by the diamine monomer component, the anhydride monomer component, and the polyimide modifier, as well as the photoinitiator, the photo cross-linking agent, and the thermal cross-linking agent, the photosensitive composition can be applied in exposure and developing processes, and can be developed using an alkaline aqueous solution and can be aged at a low temperature of less than 200° C. without the use of a nitrogen oven in the manufacturing process. More specifically, since the photosensitive composition includes polyimide formed by the diamine monomer component, the anhydride monomer component, and the polyimide modifier, as well as the photoinitiator, the photo cross-linking agent, and the thermal cross-linking agent, the product obtained after exposure and developing processes can have good acid and alkali resistance, solder resistance, solvent resistance, and thermal stability, and can have good adhesion with copper foil. As a result, the photosensitive composition of the invention can be applied in the flexible circuit board of a high-density circuit.

Moreover, the photosensitive composition can further include an adhesion promoter. Specifically, examples of the adhesion promoter include (but are not limited to): N-(triethoxysilylpropyl)urea, 1H-1,2,4-triazole-3-thiol, or 2-amino-5-mercapto-1,3,4-thiadiazole. In the present embodiment, based on the total weight of the photosensitive composition, the content of the adhesion promoter is 0.1 wt % to 1.3 wt %, preferably 0.5 wt % to 0.9 wt %. It should be mentioned that, since the photosensitive composition further includes the adhesion promoter, the product obtained after exposure and developing processes can have better adhesion with copper foil so as to have better acid and alkali resistance.

Moreover, without compromising the effects of the photosensitive composition of the invention, the photosensitive composition can further contain an additive as needed. The additive includes (but is not limited to): a filler, colorant, flame retardant, defoamer, or a combination thereof.

The features of the invention are more specifically described in the following with reference to Examples 1 to 5 and Comparative Example 1. Although the following Examples 1 to 5 are described, the materials used and the amounts and ratios thereof, as well as handling details and handling processes . . . etc. can be suitably modified without exceeding the scope of the invention. Accordingly, restrictive interpretation should not be made to the invention based on the examples described below.

Information of the main materials and equipment used in the preparation of the photosensitive compositions of Examples 1 to 5 and Comparative Example 1 is as shown below.

Diamine Monomer Component:

long-chain aliphatic diamine monomer, product name: Priamine™ 1074-dimer diamine, made by Croda Japan, including a C₃₆ main chain;

methylene bis(anthranilic acid) (hereinafter MBAA) purchased from Wakayama Seika Kogyo Co., Ltd.;

3,5-diamino-1,2,4-triazole (hereinafter DTA) purchased from Tong Sing Corporation.

Anhydride Monomer Component:

bis-(3-phthalyl anhydride)ether (hereinafter ODPA) purchased from TCI Corporation;

1,2,4-benzenetricarbovylic anhydride (hereinafter TMA) purchased from Tong Sing Corporation.

Polyimide Modifier:

glycidyl methacrylate purchased from Chembridge Corporation.

Photoinitiator:

phenyl bis(2,4,6-trimethylphenyl methyl)phosphine oxide purchased from Chembridge Corporation.

Photo Cross-Linking Agent:

trimethylolpropane trimethacrylate monomer purchased from Eternal Corporation.

Thermal Cross-Linking Agent:

1,3-phenylenebisoxazoline purchased from Mikuni Pharmaceutical Industrial Co., Ltd.

Adhesion Promoter:

2-amino-5-mercapto-1,3,4-thiadiazole purchased from Uni-Onward Corporation;

1H-1,2,4-triazole-3-thiol purchased from Uni-Onward Corporation;

N-(triethoxysilylpropyl)urea purchased from Uni-Onward Corporation.

### REFERENCE EXAMPLE

First, the long-chain aliphatic diamine monomer, MBAA, and DTA were dissolved in N-methyl-2-pyrrolidone used as the solvent at 70° C. in a 1000 mL glass reactor to form a diamine monomer mixed solution. Next, at 70° C., ODPA was added in the diamine monomer mixed solution and the mixture was stirred for 2 hours, and then TMA was added and the mixture was stirred again for 2 hours to obtain a polyamic acid solution having a solid content of about 40%.

Next, triphenylphosphine (TPP) used as the catalyst, toluene used as the azeotropic agent, and the polyamic acid were mixed to form a pre-reaction solution. Next, the pre-reaction solution was reacted in an imidization reaction under the following conditions: stirring at temperature conditions of 150° C., 160° C., and 170° C. in order respectively for 3 hours, 1 hour, and 1 hour to obtain a solution containing soluble polyimide.

Next, TPP and hydroquinone were added in the solution containing soluble polyimide, and the mixture was stirred at a constant temperature of 95° C. for 0.5 hours to obtain a mixed solution. Next, glycidyl methacrylate was added slowly in the mixed solution, and the mixture was cooled after stirring at a constant temperature of 95° C. for 4 hours such that glycidyl methacrylate was grafted on the soluble polyimide to obtain a solution containing photosensitive polyimide. It should be mentioned that, gelling due to cross-link between glycidyl methacrylate and soluble polyimide can be prevented by using hydroquinone.

Next, aerosolized silicon dioxide, a pigment, TPP, a trimethylolpropane trimethacrylate monomer, a defoamer, and the solution containing photosensitive polyimide were stirred and mixed for 10 minutes using a Chain Taro mixer, and then the mixture was dispersed using a three-roller machine to obtain a mixed solution. 1,3-phenylenebisoxazoline and phenyl bis(2,4,6-trimethylphenyl methyl)phosphine oxide were stirred in N-methylpyrrolidone for 5 minutes by using a Chain Taro mixer for uniform mixing in advance, and then the mixture was added in the mixed solution to obtain a photosensitive composition having a solid content of about 50%.

### Example 1

The photosensitive composition of Example 1 was manufactured based on the same manufacturing process as the Reference Example, wherein in the preparation process of the photosensitive polyimide, based on the total number of moles of the diamine monomer component, the content of the long-chain aliphatic diamine monomer is 25 mol %, the content of MBAA is 70 mol %, and the content of DTA is 5 mol %; in the preparation process of the photosensitive polyimide, based on the total number of moles of the anhydride monomer component, the content of ODPA is 90 mol %, and the content of TMA is 10 mol %; and based on the total weight of the photosensitive composition of Example 1, the content of the photosensitive polyimide prepared at the above ratios is 75 wt %, the content of phenyl bis(2,4,6-trimethylphenyl methyl)phosphine oxide is 2.5 wt %, the content of the trimethylolpropane trimethacrylate monomer is 7.5 wt %, and the content of 1,3-phenylenebisoxazoline is 15 wt %.

### Example 2

The photosensitive composition of Example 2 was manufactured based on the same manufacturing process as Example 1, and the difference is mainly in that: in Example 1, based on the total number of moles of the diamine monomer component, the content of the long-chain aliphatic diamine monomer is 25 mol %, the content of MBAA is 70 mol %, and the content of DTA is 5 mol %; in Example 2, based on the total number of moles of the diamine monomer component, the content of the long-chain aliphatic diamine monomer is 20 mol %, the content of MBAA is 70 mol %, and the content of DTA is 10 mol %.

### Example 3

The photosensitive composition of Example 3 was manufactured based on the same manufacturing process as Example 2, and the difference is mainly in that: in Example 3, in the steps of stirring and mixing the solution containing photosensitive polyimide using a Chain Taro mixer and dispersing the solution containing photosensitive polyimide using a three-roller machine, 2-amino-5-mercapto-1,3,4-thiadiazole was further added for stirring, mixing, and dispersion. Specifically, based on the total weight of the photosensitive composition of Example 3, the content of the photosensitive polyimide is 74.3 wt %, the content of phenyl bis(2,4,6-trimethylphenyl methyl)phosphine oxide is 2.5 wt %, the content of the trimethylolpropane trimethacrylate monomer is 7.5 wt %, the content of 1,3-phenylenebisoxazoline is 15 wt %, and the content of 2-amino-5-mercapto-1,3,4-thiadiazole is 0.7 wt %.

### Example 4

The photosensitive composition of Example 4 was manufactured based on the same manufacturing process as Example 3, and the difference is mainly in that: in Example 3, the adhesion promoter used was 2-amino-5-mercapto-1,3,4-thiadiazole; and in Example 4, the adhesion promoter used was 1H-1,2,4-triazole-3-thiol.

### Example 5

The photosensitive composition of Example 5 was manufactured based on the same manufacturing process as Example 3, and the difference is mainly in that: in Example 3, the adhesion promoter used was 2-amino-5-mercapto-1,3,4-thiadiazole; and in Example 5, the adhesion promoter used was N-(triethoxysilylpropyl)urea.

### Comparative Example 1

The photosensitive composition of Comparative Example 1 was manufactured based on the same manufacturing process as Example 1, and the difference is mainly in that: in Example 1, the diamine monomer component included the long-chain aliphatic diamine monomer, MBAA, and DTA; and in Comparative Example 1, the diamine monomer component only included the long-chain aliphatic diamine monomer and MBAA, that is, in Comparative Example 1, the triazole compound was not used in the preparation process of the photosensitive polyimide at all, and the diamine monomer component only included two types of diamine monomers. Moreover, in Comparative Example 1, based on the total number of moles of the diamine monomer component, the content of the long-chain aliphatic diamine monomer is 30 mol % and the content of MBAA is 70 mol %.

After the preparation of the photosensitive compositions of Examples 1 to 5 and Comparative Example 1 is complete, the photosensitive compositions were respectively exposed and developed to form polyimide films of Examples 1 to 5 and Comparative Example 1 having line widths and spacings at resolutions reaching 50 micrometers, wherein the thicknesses of the films were 19 micrometers. Hereinafter, the preparation method of the polyimide film is described using the photosensitive composition of Example 1 as example.

First, the photosensitive composition of Example 1 was printed on an electrolytic copper foil having a thickness of 12 μm using a screen printing method. Next, the photosensitive composition was baked at a pre-bake temperature of 70° C. for 10 minutes using a hot air oven to form a photosensitive polyimide film on the electrolytic copper foil, and the thickness of the photosensitive polyimide film was 20 micrometers.

Next, a film was disposed on a side of the photosensitive polyimide film away from the electrolytic copper foil, and the photosensitive polyimide film was exposed via light having an energy of 500 mj/cm² using an unfiltered mercury arc lamp, wherein the light having an energy of 500 mj/cm² is equivalent to the 5-step to 7-step in the Stouffer 21-step tablet.

Next, the exposed photosensitive polyimide film was developed using an ultrasonic oscillator at 30° C. by using an aqueous solution containing 1 volume percentage of sodium carbonate as the developing agent, and the developing time was 90 seconds. Next, the developed photosensitive polyimide film was washed using clean water for 30 seconds, and then the washed photosensitive polyimide film was dried using an air gun.

Lastly, the dried photosensitive polyimide film was aged for 60 minutes at an aging temperature of 160° C. using a hot air circulation oven to obtain the polyimide film of Example 1 on the electrolytic copper foil.

It should be mentioned that, it can be known from the preparation method of the polyimide film that, the photosensitive composition of the invention can be printed on copper foil via a screen printing method, and therefore the photosensitive composition of the invention is suitable for a circuit board. Moreover, during the exposure process, the light energy needed for the photosensitive composition of the invention is 500 mj/cm², and therefore the application of the photosensitive composition of the invention in the manufacturing process of a circuit board can lower manufacturing costs. Moreover, in the developing process, the photosensitive composition of the invention after exposure is developed using an aqueous solution of 1 volume percentage of sodium carbonate, indicating that when applied in exposure and developing processes, the photosensitive composition of the invention can be developed using a weakly-alkaline developing agent, and the weakly-alkaline developing agent is a common developing agent in the manufacturing process of a circuit board. In other words, the photosensitive composition of the invention can be developed after exposure without the use of a specific type of developing agent (such as a developing agent containing an organic solvent) that is not a common developing agent used in the manufacturing process of a circuit board. Moreover, during the aging process, the aging temperature needed for the photosensitive composition of the invention after exposure and development is 160° C. and a nitrogen oven is not needed, and therefore the photosensitive composition of the invention can lower manufacturing costs when applied in the manufacturing process of a circuit board. It can be known from the above that, by including polyimide formed by the diamine monomer component, the anhydride monomer component, and the polyimide modifier, as well as the photoinitiator, the photo cross-linking agent, and the thermal cross-linking agent, the photosensitive composition of the invention can meet the current manufacturing conditions of a flexible circuit board of a high-density circuit.

After the polyimide films of Examples 1 to 5 and Comparative Example 1 were prepared, measurements of thermal decomposition temperature, acid resistance, alkali resistance, solvent resistance, and solder resistance were respectively performed on the polyimide films of Examples 1 to 5 and Comparative Example 1, and measurements of peel strength were respectively performed on the polyimide films of Examples 1 to 5 and Comparative Example 1 disposed on electrolytic copper foil. The above measurements are as described below, and the measurement results are shown in Table 1.

### <Measurement of Thermal Decomposition Temperature>

First, the polyimide films of Examples 1 to 5 and Comparative Example 1 were respectively used in amounts of 0.5 g to 0.8 g as testing film materials. Then, the film materials were heated from 30° C. to 600° C. under the conditions of a nitrogen atmosphere and a heating rate set to 10° C./min using a thermal weight loss analyzer (made by Seiko Instrument Inc., product name: EXSTAR 6000), and the temperature measured at a weight loss of 5% of the film materials was used as the thermal decomposition temperature (° C.). In the standards set by the industry, a thermal decomposition temperature of the polyimide film reaching 300° C. or more represents good thermal stability.

### <Measurement of Acid Resistance>

The polyimide films of Examples 1 to 5 and Comparative Example 1 were respectively soaked in a hydrochloric acid solution having 10 volume percentage concentration for 15 minutes, and the polyimide films were visually observed and evaluated. The evaluation criteria are as shown below.

◯: no peeling on film and copper foil surface

Δ: slight peeling on film and copper foil surface

### <Measurement of Alkali Resistance>

The polyimide films of Examples 1 to 5 and Comparative Example 1 were respectively soaked in a sodium hydroxide solution having 10 volume percentage concentration for 15 minutes, and the polyimide films were visually observed and evaluated. The evaluation criteria are as shown below.

◯: no peeling on film and copper foil surface

Δ: slight peeling on film and copper foil surface

### <Measurement of Solvent Resistance>

In one experiment, the polyimide films of Examples 1 to 5 and Comparative Example 1 were respectively soaked in an isopropyl alcohol (IPA) solution for 15 minutes, and then the polyimide films were visually observed and evaluated. In another experiment, the polyimide films of Examples 1 to 5 and Comparative Example 1 were respectively soaked in a methyl ethyl ketone (MEK) solution for 15 minutes, and then the polyimide films were visually observed and evaluated. The evaluation criteria are as shown below.

◯: no peeling on film and copper foil surface

Δ: slight peeling on film and copper foil surface

### <Measurement of Solder Resistance>

The polyimide films of Examples 1 to 5 and Comparative Example 1 were respectively pre-heated and soldered afloat at 300° C. continuously for 30 seconds based on the provisions of IPC-TM-650 2.4.13, and then the polyimide films were visually observed and evaluated. The evaluation criteria are as shown below.

◯: no foaming or peeling on film

Δ: slight foaming or peeling on film

### <Measurement of Peel Strength>

First, the polyimide films of Examples 1 to 5 and Comparative Example 1 disposed on electrolytic copper foil were respectively cut into test samples having a width of 0.3175 mm along with the electrolytic copper foil. Then, the test samples were stretched to a stretch length of 30 mm using a universal testing machine (made by Shimadzu Scientific Instruments Co., Ltd., product name: AG-IS) under the condition of a tensile speed set to 50.8 mm/min, and the peel strength (kgf/cm) at this point was obtained. It should be mentioned that, a greater adhesion between the polyimide film and the electrolytic copper foil indicates the interface between the two is less readily damaged by external force. In other words, in Table 1, a higher peel strength value represents better peel strength and stronger adhesion between the polyimide film and electrolytic copper foil.

TABLE 1

| | | | | | | Comparative |
|---|---|---|---|---|---|---|
| | Example 1 | Example 2 | Example 3 | Example 4 | Example 5 | Example 1 |
| Thermal | 330 | 331 | 329 | 330 | 328 | 321 |
| decomposition | | | | | | |
| temperature (° C.) | | | | | | |
| Acid | ◯ | ◯ | ◯ | ◯ | ◯ | Δ |
| resistance | | | | | | |
| Alkali | ◯ | ◯ | ◯ | ◯ | ◯ | Δ |
| resistance | | | | | | |
| Solvent | ◯ | ◯ | ◯ | ◯ | ◯ | ◯ |
| resistance-IPA | | | | | | |
| Solvent | ◯ | ◯ | ◯ | ◯ | ◯ | ◯ |
| resistance-MEK | | | | | | |
| Solder | ◯ | ◯ | ◯ | ◯ | ◯ | ◯ |
| resistance | | | | | | |
| Peel strength | 0.324 | 0.378 | 0.429 | 0.410 | 0.412 | 0.257 |
| (kgf/cm) | | | | | | |

It can be known from Table 1 that, the polyimide films of Examples 1 to 5 all have good thermal decomposition temperature, acid resistance, alkali resistance, solvent resistance, solder resistance, and peel strength; and the polyimide film of Comparative Example 1 has poor acid and alkali resistance and peel strength. Accordingly, in comparison to a photosensitive composition without the triazole compound as the diamine monomer and without the adhesion promoter, by including polyimide formed by the diamine monomer component, the anhydride monomer component, and the polyimide modifier, as well as the photoinitiator, the photo cross-linking agent, and the thermal cross-linking agent, the product formed by the photosensitive composition of the invention after exposure and development has good thermal stability, acid and alkali resistance, solvent resistance, and solder resistance, and has good adhesion with copper foil. More specifically, since the photosensitive composition of the invention can meet current manufacturing conditions of a flexible circuit board of a high-density circuit, and the product formed by the photosensitive composition of the invention after exposure and development has good thermal stability, acid and alkali resistance, solvent resistance, and solder resistance, and has good adhesion with copper foil, the photosensitive composition of the invention is suitable for a flexible circuit board of a high-density circuit.

Moreover, it can be known from Table 1 that, in comparison to the polyimide films of Example 1 and Example 2, the polyimide films of Examples 3 to 5 have better peel strength. Accordingly, by further including the adhesion promoter, the product obtained by the photosensitive composition of the invention after exposure and development can have better adhesion with copper foil.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A photosensitive composition, comprising:
a composition for forming polyimide, comprising:
a diamine monomer component comprising a long-chain aliphatic diamine monomer, a carboxylic acid-containing diamine monomer, and a triazole compound;
an anhydride monomer component comprising a dianhydride monomer and a monoanhydride monomer; and
a polyimide modifier, wherein the polyimide modifier has a double bond and an epoxy group;
a photoinitiator;
a photo cross-linking agent; and
a thermal cross-linking agent.

2. The photosensitive composition of claim 1, wherein the long-chain aliphatic diamine monomer has a C₆ to C₄₀ main chain.

3. The photosensitive composition of claim 1, wherein the carboxylic acid-containing diamine monomer comprises methylene bis(anthranilic acid) or 3,5-diaminobenzoic acid.

4. The photosensitive composition of claim 1, wherein the triazole compound comprises 3,5-diamino-1,2,4-triazole or benzotriazole.

5. The photosensitive composition of claim 1, wherein the dianhydride monomer comprises bis-(3-phthalyl anhydride)ether, 3,3′,4,4′-benzophenonetetracarboxylic dianhydride, 3,3′,4,4′-biphenyltetracarboxylic dianhydride, bicyclo[2.2.2]oct-7-ene-2,3,5,6-tetracarboxylic dianhydride, or 4,4′-(hexafluoro-isopropylidene)diphthalic anhydride.

6. The photosensitive composition of claim 1, wherein the monoanhydride monomer comprises 1,2,4-benzenetricarbovylic anhydride or phthalic anhydride.

7. The photosensitive composition of claim 1, wherein based on a total number of moles of the diamine monomer component, a content of the long-chain aliphatic diamine monomer is 15 mol % to 30 mol %, a content of the carboxylic acid-containing diamine monomer is 65 mol % to 75 mol %, and a content of the triazole compound is 3 mol % to 12 mol %.

8. The photosensitive composition of claim 1, wherein based on a total number of moles of the anhydride monomer component, a content of the dianhydride monomer is 80 mol % to 95 mol % and a content of the monoanhydride monomer is 5 mol % to 20 mol %.

9. The photosensitive composition of claim 1, wherein a mole ratio of the diamine monomer component and the anhydride monomer component is 1:1.

10. The photosensitive composition of claim 1, wherein the polyimide modifier comprises glycidyl methacrylate or allyl glycidyl ether.

11. The photosensitive composition of claim 1, wherein based on a number of moles of the carboxylic acid-containing diamine monomer, an amount of the polyimide modifier is 0.2 mol % to 0.4 mol %.

12. The photosensitive composition of claim 1, wherein the photoinitiator comprises phenyl bis(2,4,6-trimethylphenyl methyl)phosphine oxide or 2-benzyl-2-(dimethylamino)-1-[4-(4-morpholinyl)phenyl]-1-butanone.

13. The photosensitive composition of claim 1, wherein the photo cross-linking agent comprises a trimethylolpropane trimethacrylate monomer, pentaerythritol triacrylate, 1,6-hexanediol diacrylate, dipentaerythritol hexaacrylate, or tri(propylene glycol)diacrylate.

14. The photosensitive composition of claim 1, wherein the thermal cross-linking agent comprises 1,3-phenylene-bis-oxazoline or an epoxy resin.

15. The photosensitive composition of claim 1, wherein based on a total weight of the photosensitive composition, a content of polyimide formed by the composition for forming polyimide is 65 wt % to 85 wt %, a content of the photoinitiator is 0.5 wt % to 5 wt %, a content of the photo cross-linking agent is 4 wt % to 10 wt %, and a content of the thermal cross-linking agent is 10 wt % to 20 wt %.

16. The photosensitive composition of claim 1, further comprising an adhesion promoter, wherein based on a total weight of the photosensitive composition, a content of the adhesion promoter is 0.1 wt % to 1.3 wt %.

17. The photosensitive composition of claim 16, wherein the adhesion promoter comprises N-(triethoxysilylpropyl)urea, 1H-1,2,4-triazole-3-thiol, or 2-amino-5-mercapto-1,3,4-thiadiazole.
